(19) United States
(12) Patent Application Publication
(10) Pub. No.: US 2026/0351296 A1
(43) Pub. Date: Nov. 5, 2026

(54) SEMICONDUCTOR DEVICE AND OPERATING METHOD OF THE SAME

(71) Applicant: SK hynix Inc., Icheon-si (KR)

(72) Inventor: Gap Sok DO, Icheon-si (KR)

(21) Appl. No.: 19/359,482

(22) Filed: Oct. 15, 2025

(30) Foreign Application Priority Data
Apr. 30, 2025 (KR) 10-2025-0057273

(51) Int. Cl. G11C 5/14; G11C 5/06

(52) U.S. Cl. CPC G11C 5/14; G11C 5/06

(57) ABSTRACT

A semiconductor device includes a first memory cell that is connected between a first bit line and a word line, a second memory cell that is connected between a second bit line and the word line, a first voltage supply circuit configured to supply a first logic input voltage to the first memory cell, a second voltage supply circuit configured to supply a second logic input voltage to the second memory cell, and a third voltage supply circuit configured to supply one of a first logic operation voltage and a second logic operation voltage to the word line. Each of the first memory cell and the second memory cell is a component of the device that performs a specific logic operation.

### CROSS-REFERENCE TO RELATED APPLICATION

This application claims priority under 35 U.S.C. §119(a) to Korean Patent Application No. 10-2025-0057273, filed in the Korean Intellectual Property Office on Apr. 30, 2025, the entire contents of which are incorporated herein by reference.

### BACKGROUND

### 1.TECHNICAL FIELD

Embodiments relate to an integrated circuit technology and, more particularly, to a semiconductor device and an operating method of the same.

### 2.RELATED ART

Recently, as an electronic device is reduced in size, has lower power consumption and higher performance, and is diversified, memory capable of storing information is required for various electronic devices, such as computers and portable communication devices. Furthermore, research on memory having various characteristics continues to be conducted.

Memory that is being researched also includes memory capable of storing data by using a characteristic in which the memory switches between different resistance states depending on a voltage or current thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, a semiconductor device may include a first memory cell that is connected between a first bit line and a word line, a second memory cell that is connected between a second bit line and the word line, a first voltage supply circuit configured to supply a first logic input voltage to the first bit line in order to use the first memory cell in a logic operation, a second voltage supply circuit configured to supply a second logic input voltage to the second bit line in order to use the second memory cell in the logic operation, and a third voltage supply circuit configured to supply one of a first logic operation voltage and a second logic operation voltage to the word line in order to use the first memory cell and the second memory cell in the logic operation.

In an embodiment, an operating method of a semiconductor device may include writing a first memory cell that is connected between a first bit line and a word line, writing a second memory cell that is connected between a second bit line and the word line in a state identical with the state of the first memory cell, supplying a first logic input voltage to the first bit line, supplying a second logic input voltage to the second bit line, and supplying the word line with one of a first logic operation voltage and a second logic operation voltage having a lower level than the first logic operation voltage depending on the type of logic operation for which the first memory cell and the second memory cell are used.

In still another embodiment, a memory device may include a first memory cell that is connected between a first bit line and a word line and written so that a current flows better in a second direction than in a first direction, a second memory cell that is connected between a second bit line and the word line and written so that a current flows better in the second direction than in the first direction, a first voltage supply circuit configured to supply a first logic input voltage to the first bit line, a second voltage supply circuit configured to supply a second logic input voltage to the second bit line, and a third voltage supply circuit configured to supply the word line with a second logic operation voltage having a lower level than a first logic operation voltage. The results of an OR operation on the levels of the first logic input voltage and the second logic input voltage may correspond to a voltage level of the word line.

In still another embodiment, a memory device may include a first memory cell that is connected between a first bit line and a word line and written so that a current flows better in a second direction than in a first direction, a second memory cell that is connected between a second bit line and the word line and written so that a current flows better in the second direction than in the first direction, a first voltage supply circuit configured to supply a first logic input voltage to the first bit line, a second voltage supply circuit configured to supply a second logic input voltage to the second bit line, and a third voltage supply circuit configured to supply the word line with a second logic operation voltage having a lower level than a first logic operation voltage. The results of an OR operation on the levels of the first logic input voltage and the second logic input voltage may correspond to a voltage level of the word line.

### BRIEF DESCRIPTION OF THE DRAWINGS

FIG. 1 is a diagram for describing a memory cell of a semiconductor device according to an embodiment of the present disclosure.

FIGS. 2 and 3 are diagrams for describing write operations of the semiconductor device according to an embodiment of the present disclosure.

FIG. 4 is a diagram for describing a read operation of the semiconductor device according to an embodiment of the present disclosure.

FIGS. 5 and 6 are diagrams for describing a semiconductor device according to an embodiment of the present disclosure.

FIGS. 7 and 8 are diagrams for describing a semiconductor device according to another embodiment of the present disclosure.

FIG. 9 is a diagram for describing a memory cell array according to an embodiment of the present disclosure.

### DETAILED DESCRIPTION

Hereinafter, some embodiments of the present disclosure are described with reference to the accompanying drawings.

Embodiments of the present disclosure relate to a technology in which some areas of a memory cell array are used in a logic operation.

It is possible to embody a semiconductor device capable of an arithmetic operation.

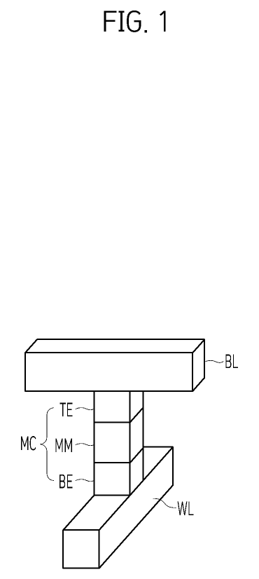

FIG. 1 is a diagram for describing a memory cell of a semiconductor device according to an embodiment of the present disclosure.

Referring to FIG. 1, a memory cell MC of the semiconductor device according to an embodiment of the present disclosure may be disposed between a bit line BL and a word line WL. Furthermore, the memory cell MC may be electrically connected to the bit line BL and the word line WL. FIG. 1 illustrates that the bit line BL is disposed over the word line WL, but the bit line BL may be disposed under the word line WL according to an embodiment. Furthermore, each of the bit line BL and the word line WL may include a conductive material.

The memory cell MC may include a first electrode TE, a memory material MM, and a second electrode BE. The memory material MM may be placed between the first electrode TE and the second electrode BE. In this case, each of the first and second electrodes TE and BE may include a conductive material. The level of the threshold voltage of the memory material MM may be changed depending on the direction of a current that flows through the memory material MM. The memory material MM may include a chalcogenide-series material.

For example, the second electrode BE may be formed on the word line WL. The memory material MM may be formed on the second electrode BE. The first electrode TE may be formed on the memory material MM. The bit line BL may be formed on the first electrode TE. In this case, the first electrode TE at a higher location than the second electrode BE may be named an upper electrode TE, and the second electrode BE at a lower location than the first electrode TE may be named a lower electrode BE, depending on locations at which the first electrode TE and the second electrode BE are formed.

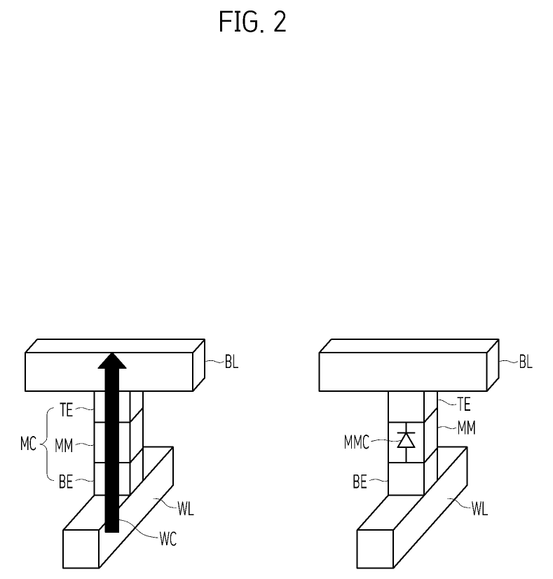

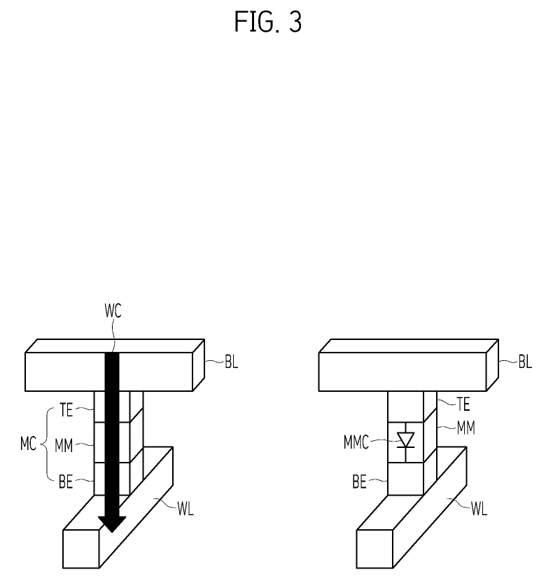

FIGS. 2 and 3 are diagrams for describing write operations of the semiconductor device according to an embodiment of the present disclosure.

FIG. 2 may be a diagram illustrating a write operation in which the write current WC flows from the word line WL to the bit line BL through the memory cell MC. The write operation may be an operation of supplying the word line WL and the bit line BL with voltages such that a difference between the voltage levels of the word line WL and the bit line BL is greater than the level of a voltage to the extent that the memory cell MC is turned on. In this case, a voltage higher than a voltage that is supplied to the bit line BL may be supplied to the word line WL.

Such a write operation may be an operation of changing the memory material characteristic MMC of the memory material MM so that a current flows better in a first direction rather than a second direction. In this case, the memory material characteristic MMC may be similar to the characteristic of a diode that enables a current to flow in the first direction. The first direction may be a direction in which a current flows from the word line WL to the bit line BL through the memory material MM. The second direction may be a direction in which a current flows from the bit line BL to the word line WL through the memory material MM.

FIG. 3 may be a diagram illustrating a write operation in which the write current WC flows from the bit line BL to the word line WL through the memory cell MC. The write operation may be an operation of supplying the bit line BL and the word line WL with voltages such that a difference between the voltage levels of the bit line BL and the word line WL is greater than the level of a voltage to the extent that the memory cell MC is turned on. In this case, a voltage higher than a voltage that is supplied to the word line WL may be supplied to the bit line BL.

Such a write operation may be an operation of changing the memory material characteristic MMC of the memory material MM so that a current flows better in a second direction than in a first direction. In this case, the memory material characteristic MMC may be similar to the characteristic of a diode that enables a current to flow in the second direction. The first direction may be a direction in which a current flows from the word line WL to the bit line BL through the memory material MM. The second direction may be a direction in which a current flows from the bit line BL to the word line WL through the memory material MM.

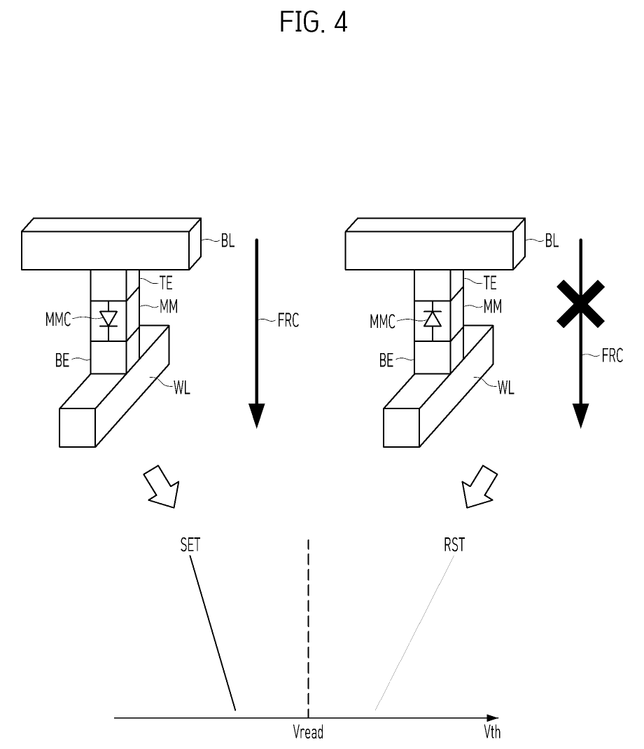

FIG. 4 is a diagram for describing a read operation of the semiconductor device according to an embodiment of the present disclosure.

Referring to FIG. 4, the read operation may be an operation of determining the state of the memory cell MC by supplying the bit line BL with a voltage having a higher level than a voltage that is supplied to the word line WL. In this case, the read operation may be an operation of causing a read current FRC having the same direction as the write current WC to flow after the start of the write operation illustrated in FIG. 3. Furthermore, a difference between the voltage levels of the bit line BL and the word line WL after the start of a read operation may correspond to the level of a read voltage Vread. The read voltage Vread may have a voltage level between the level of the threshold voltage of the memory cell MC according to the write operation described with reference to FIG. 2 and the level of the threshold voltage of the memory cell MC according to the write operation described with reference to FIG. 3.

Accordingly, when the read operation is performed on the memory cell MC having the memory material characteristic MMC changed as illustrated in FIG. 4 through the write operation in which the write current WC flows from the bit line BL to the word line WL as illustrated in FIG. 3, the read current FRC may flow from the bit line BL to the word line WL through the memory cell MC that is turned on. At this time, the memory cell MC may be turned on because the level of the threshold voltage of the memory cell MC having the memory material characteristic MMC changed by the write operation described with reference to FIG. 3 is lower than the level of the read voltage Vread.

When the read operation is performed on the memory cell MC having the memory material characteristic MMC changed as illustrated in FIG. 4 through the write operation described with reference to FIG. 2, the read current FRC might not substantially flow. At this time, the memory cell MC might not be turned on because the level of the threshold voltage of the memory cell MC having the memory material characteristic MMC changed by the write operation described with reference to FIG. 2 is higher than the level of the read voltage Vread. Accordingly, the read current FRC might not substantially flow.

The state of the memory cell MC having a threshold voltage having a lower level than the read voltage Vread may be called a set state SET. The state of the memory cell MC having a threshold voltage having a higher level than the read voltage Vread may be called a reset state RST.

That is, the state of the memory cell MC may be changed into the set state SET through the write operation described with reference to FIG. 3. Furthermore, the state of the memory cell MC may be changed into the reset state RST through the write operation described with reference to FIG. 2. In this case, the write operation of changing the state of the memory cell MC into the set state SET may be named a set write operation. The write operation of changing the state of the memory cell MC into the reset state RST may be named a reset write operation.

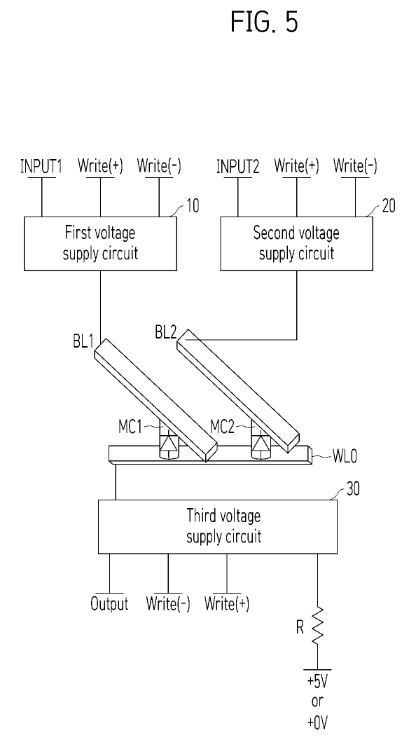

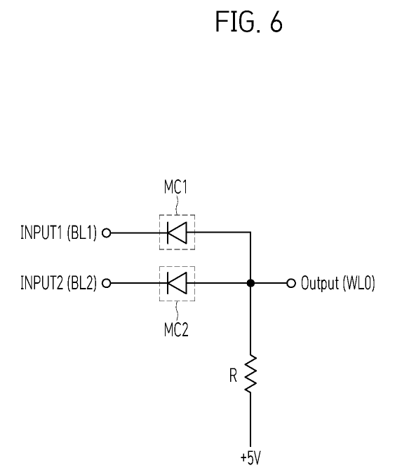

FIGS. 5 and 6 are diagrams for describing a semiconductor device according to an embodiment of the present disclosure.

FIG. 5 is a diagram for describing a semiconductor device that embodies a first logic circuit (e.g., an AND operation logic circuit) having two input terminals and one output terminal by using memory cells having characteristics described with reference to FIGS. 1-4.

Referring to FIG. 5, the AND operation logic circuit according to an embodiment of the present disclosure may include two memory cells MC1 and MC2 that are connected between one word line WL0 and two bit lines BL1 and BL2. At this time, each of the two memory cells MC1 and MC2 may be in the state in which the memory cell has been written so that a current flows from the word line WL0 to the two bit lines BL1 and BL2, that is, a first state (e.g., the reset state RST). In some embodiments, each of first and second memory cells MC1 and MC1 may be a component of a semiconductor device that performs a specific logic operation (e.g., the AND operation as shown in FIGS. 5 and 6). For example, each of first and second memory cells MC1 and MC1 may be a two-terminal component (e.g., a diode) that allows a current to flow in a first direction from the word line WL0 to a corresponding one of the first and second bit lines BL1 and BL2 and block in a second direction from the corresponding one of the first and second bit lines BL1 and BL2 to the word line WL0.

The first memory cell MC1 may be disposed between the word line WL0 and the first bit line BL1.

The second memory cell MC2 may be disposed between the word line WL0 and the second bit line BL2.

A first voltage supply circuit 10 may supply one of a first logic input voltage INPUT1, a first write voltage Write(+), and a second write voltage Write(-) to the first bit line BL1.

A second voltage supply circuit 20 may supply one of a second logic input voltage INPUT2, the first write voltage Write(+), and the second write voltage Write(-) to the second bit line BL2.

A third voltage supply circuit 30 may supply one of the first write voltage Write(+), the second write voltage Write(-), a first logic operation voltage (e.g., +5 V), and a second logic operation voltage (e.g., 0 V) to the word line WL0. At this time, when supplying one of the first logic operation voltage +5 V and the second logic operation voltage +0 V to the word line WL0 through a resistance element R, the third voltage supply circuit 30 may electrically connect the word line WL0 and an operation output terminal Output.

In this case, the first write voltage Write(+) may be a higher voltage level than the second write voltage Write(-). The first write voltage Write(+) may have a positive voltage level, and the second write voltage Write(-) may have a negative voltage level. A difference between the levels of the first write voltage Write(+) and the second write voltage Write(-) may be greater than the level of the threshold voltage of each of the first memory cell MC1 and the second memory cell MC2 that are in the reset state RST. The first logic operation voltage +5 V may have a higher voltage level than the second logic operation voltage +0 V. A difference between the levels of the first logic operation voltage +5 V and the second logic operation voltage +0 V may be smaller than a difference between the levels of the first write voltage Write(+) and the second write voltage Write(-). An example in which the first logic operation voltage +5 V is 5 V and the second logic operation voltage +0 V is a ground voltage +0 V is described, but the first logic operation voltage +5 V may be higher than or lower than 5 V and the second logic operation voltage +0 V may be higher than or lower than 0 V. Furthermore, each of the first logic input voltage INPUT1 and the second logic input voltage INPUT2 may have the level of the first logic operation voltage +5 V or the level of the second logic operation voltage +0 V.

An operation of setting the states of the first memory cell MC1 and the second memory cell MC2 in order to operate the semiconductor device constructed as above according to an embodiment of the present disclosure as the AND operation logic circuit is described as follows.

The first memory cell MC1 may be written to the reset state RST. For example, the second write voltage Write(-)may be supplied from the first voltage supply circuit 10 to the first bit line BL1. The first write voltage Write(+)may be supplied from the third voltage supply circuit 30 to the word line WL0. The first memory cell MC1 that is connected between the first bit line BL and the word line WL0 may be turned on by a difference between the levels of the first write voltage Write(+) and the second write voltage Write(-), and thus may be written in the reset state RST.

The second memory cell MC2 may be written to the reset state RST. For example, the second write voltage Write(-) may be supplied from the second voltage supply circuit 20 to the second bit line BL2. The first write voltage Write(+) may be supplied from the third voltage supply circuit 30 to the word line WL0. The second memory cell MC2 that is connected between the second bit line BL2 and the word line WL0 may be turned on by a difference between the levels of the first write voltage Write(+) and the second write voltage Write(-), and thus may be written to the reset state RST.

The first memory cell MC1 and the second memory cell MC2 may be separately written to the reset state RST or may be substantially simultaneously written to the reset state RST. Specifically, each of the first and second memory cells MC1 and MC2 may be written to the reset state RST by causing a current to flow from the word line WL0 to a corresponding one of the first bit line BL1 and the second bit line BL2.

After the first memory cell MC1 and the second memory cell MC2 have been written to the reset state RST, an AND operation may be performed by using the first memory cell MC1 and the second memory cell MC2 that are in the reset state RST.

As illustrated in FIG. 5, a case in which the first memory cell MC1 and the second memory cell MC2 are in the reset state RST may be illustrated in the form of an equivalent circuit as in FIG. 6.

An operation of the AND operation is described as follows with reference to FIGS. 5 and 6.

The third voltage supply circuit 30 may supply the first logic operation voltage +5 V to the word line WL0, and may electrically connect the operation output terminal Output to the word line WL0. At this time, the voltage levels of the word line WL0 and the operation output terminal Output may be the level of the first logic operation voltage +5 V.

The first voltage supply circuit 10 may supply the first logic input voltage INPUT1 to the first bit line BL1.

The second voltage supply circuit 20 may supply the second logic input voltage INPUT2 to the second bit line BL2.

Accordingly, the first logic input voltage INPUT1 that is supplied from the first bit line BL1 and the first logic operation voltage +5 V that is supplied from the word line WL0 may be supplied to both ends (or terminals) of the first memory cell MC1 in the reset state RST. The first memory cell MC1 in the reset state RST may be in the state in which a current flows better in a first direction rather than a second direction. In this case, the first direction may be the direction of a current that flows from the word line WL0 to the first bit line BL1 through the first memory cell MC1. Furthermore, the second direction may be the direction of a current that flows from the first bit line BL1 to the word line WL0 through the first memory cell MC1.

For example, the first memory cell MC1 may function as a diode that allows a current to flow in the first direction from the word line WL0 to the first bit line BL1 and substantially block in the second direction from the first bit line BL1 to the word line WL0. As a result, when the voltage level of the first bit line BL1 is lower than the voltage level of the word line WL0, a current may flow in the first direction from the word line WL0 to the first bit line BL1 through the first memory cell MC1.

The second logic input voltage INPUT2 that is supplied from the second bit line BL2 and the first logic operation voltage +5 V that is supplied from the word line WL0 may be supplied to both ends of the second memory cell MC2 in the reset state RST. The second memory cell MC2 in the reset state RST may be in the state in which a current flows better in a first direction rather than a second direction. In this case, the first direction may be the direction of a current that flows from the word line WL0 to the second bit line BL2 through the second memory cell MC2. Furthermore, the second direction may be the direction of a current that flows from the second bit line BL2 to the word line WL0 through the second memory cell MC2.

For example, the second memory cell MC2 may function as a diode that allows a current to flow in the first direction from the word line WL0 to the second bit line BL2 and substantially block in the second direction from the second bit line BL2 to the word line WL0. As a result, when the voltage level of the second bit line BL2 is lower than the voltage level of the word line WL0, a current may flow in the first direction from the word line WL0 to the second bit line BL2 through the second memory cell MC2.

Accordingly, when the level of one of the first logic input voltage INPUT1 and the second logic input voltage INPUT2 is lower than the level of the first logic operation voltage +5 V, a current may flow to a bit line through a memory cell that is supplied with a logic input voltage having a lower level than the first logic operation voltage +5 V. For example, when the level of the first logic input voltage INPUT1, among the first logic input voltage INPUT1 and the second logic input voltage INPUT2, is lower than the level of the first logic operation voltage +5 V, a current may flow from the word line WL0 having the level of the first logic operation voltage +5 V to the first bit line BL1 through the first memory cell MC1. At this time, the voltage level of the operation output terminal Output having the level of the first logic operation voltage +5 V may be lowered due to the current that flows into the first bit line BL1 through the first memory cell MC1. Furthermore, when the level of the second logic input voltage INPUT2, among the first logic input voltage INPUT1 and the second logic input voltage INPUT2, is lower than the level of the first logic operation voltage +5 V, a current may flow from the word line WL0 having the level of the first logic operation voltage +5 V to the second bit line BL2 through the second memory cell MC2. At this time, the voltage level of the operation output terminal Output having the level of the first logic operation voltage +5 V may be lowered due to the current that flows into the second bit line BL2 through the second memory cell MC2. In other words, when one or both of the first logic input voltage INPUT1 and the second logic input voltage INPUT2 have a level lower than the level of the first logic operation voltage +5 V, current(s) flowing through one or both of the first and second memory cells MC1 and MC2 as well as the resistive element R may decrease a voltage level of the operation output terminal Output.

When the levels of both the first logic input voltage INPUT1 and the second logic input voltage INPUT2 are higher than the level of the first logic operation voltage +5 V, currents that flow into the first bit line and the second bit line BL1 and BL2 through the first memory cell MC1 and the second memory cell MC2 might not be generated. Accordingly, the voltage level of the operation output terminal Output having the level of the first logic operation voltage +5 V may be substantially maintained. For example, the voltage level of the operation output terminal Output may be maintained in a range from about 95% to about 105%, from about 97% to about 103%, or from about 99% to about 101% of the first logic operation voltage +5V.

In some embodiments, the level of the first logic input voltage INPUT1 is a high level when the first logic input voltage INPUT1 has substantially the same level as the first logic operation voltage +5 V and the level of the first logic input voltage INPUT1 is a low level when the first logic input voltage INPUT1 has a lower level than the first logic operation voltage +5 V. For example, the first logic input voltage INPUT1 has substantially the same level as the first logic operation voltage +5 V when an absolute difference between the the first logic input voltage INPUT1 and the first logic operation voltage +5 V is equal to or less than 5%, 3%, or 1% of the first logic operation voltage +5 V. Furthermore, in such embodiments, the level of the second logic input voltage INPUT2 is a high level when the second logic input voltage INPUT2 has substantially the same level as the first logic operation voltage +5 V and the level of the second logic input voltage INPUT2 is a low level when the second logic input voltage INPUT2 has a lower level than the first logic operation voltage +5 V. Furthermore, in these embodiments, the voltage level of the operation output terminal Output is a high level when the voltage level of the operation output terminal Output is substantially at the level of the first logic operation voltage +5 V. In these embodiments, the voltage level of the operation output terminal Output is a low level when the voltage level of the operation output terminal Output is lower than the level of the first logic operation voltage +5 V.

As a result, when the level of any one of the first logic input voltage INPUT1 and the second logic input voltage INPUT2 is a low level, the voltage level of the operation output terminal Output may be changed into a low level. Furthermore, when the levels of both the first logic input voltage INPUT1 and the second logic input voltage INPUT2 are a high level, the voltage level of the operation output terminal Output may maintain a high level. Such a change in the voltage level of the operation output terminal Output with respect to the levels of the first logic input voltage INPUT1 and the second logic input voltage INPUT2 may correspond to the results of an operation of an AND gate.

In other words, the semiconductor device according to the embodiment of FIGS. 5 and 6 may perform an AND operation on the first logic input voltage INPUT1 and the second logic input voltage INPUT2 and output a voltage level of the word line WL0 at the operation output terminal Output as a result of the AND operation. Accordingly, the semiconductor device according to an embodiment of the present disclosure can operate as the AND operation logic circuit.

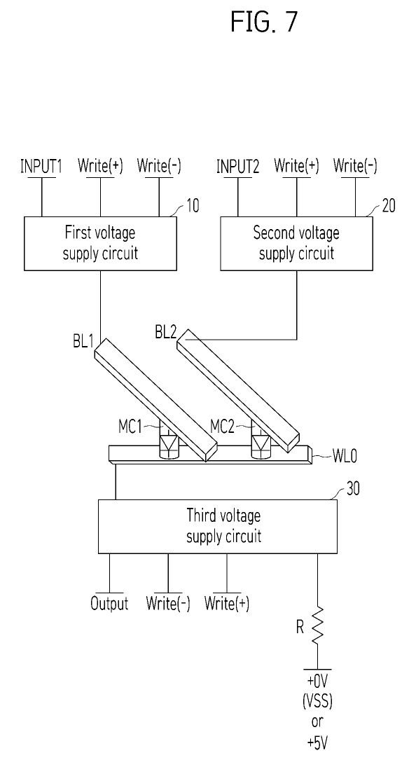

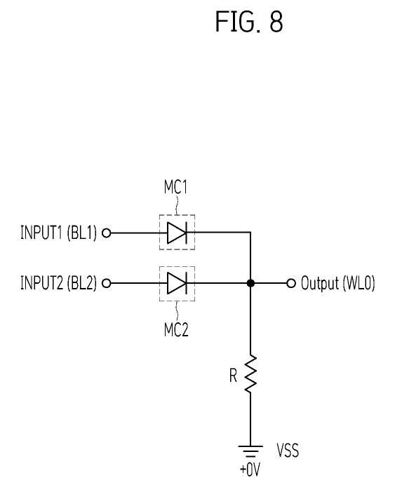

FIGS. 7 and 8 are diagrams for describing a semiconductor device according to another embodiment of the present disclosure.

FIG. 7 is a diagram for describing a semiconductor device that embodies a second logic circuit (e.g., an OR operation logic circuit) having two input terminals and one output terminal by using memory cells having characteristics described with reference to FIGS. 1-4.

Referring to FIG. 7, the OR operation logic circuit according to an embodiment of the present disclosure may include two memory cells MC1 and MC2 that are connected between one word line WL0 and two bit lines BL1 and BL2. At this time, each of the two memory cells MC1 and MC2 may be in the state in which the memory cell has been written so that a current flows from each of the first bit line and the second bit line BL1 and BL2 to the one word line WL0, that is, a second state (e.g., the set state SET). In some embodiments, each of first and second memory cells MC1 and MC2 may be a component of the semiconductor device that performs a specific logic operation (e.g., the OR operation as shown in FIGS. 7 and 8). For example, each of first and second memory cells MC1 and MC2 may be a two-terminal component (e.g., a diode) that allows a current to flow in a second direction from the corresponding one of the first and second bit lines BL1 and BL2 to the word line WL0 and block in a first direction from the word line WL0 to a corresponding one of the first and second bit lines BL1 and BL2.

The first memory cell MC1 may be disposed between the word line WL0 and the first bit line BL1.

The second memory cell MC2 may be disposed between the word line WL0 and the second bit line BL2.

A first voltage supply circuit 10 may supply one of a first logic input voltage INPUT1, a first write voltage Write(+), and a second write voltage Write(-) to the first bit line BL1.

A second voltage supply circuit 20 may supply one of a second logic input voltage INPUT2, the first write voltage Write(+), the second write voltage Write(-) to the second bit line BL2.

A third voltage supply circuit 30 may supply one of the first write voltage Write(+), the second write voltage(-), a first logic operation voltage (e.g., +5 V), and a second logic operation voltage (e.g., 0 V) to the word line WL0. At this time, when supplying one of the first logic operation voltage +5 V and the second logic operation voltage +0 V to the word line WL0 through a resistance element R, the third voltage supply circuit 30 may electrically connect the word line WL0 and an operation output terminal Output.

In this case, the first write voltage Write(+) may be a voltage having a higher level than the second write voltage Write(-). The first write voltage Write(+) may be a positive voltage level. The second write voltage Write(-) may be a negative voltage level. A difference between the levels of the first write voltage Write(+) and the second write voltage Write(-) may be greater than the level of the threshold voltage of each of the first memory cell MC1 and the second memory cell MC2 that are in the reset state RST. The first logic operation voltage +5 V may have a higher voltage level than the second logic operation voltage +0 V. A difference between the levels of the first logic operation voltage +5 V and the second logic operation voltage +0 V may be smaller than a difference between the levels of the first write voltage Write(+) and the second write voltage Write(-). An example in which the first logic operation voltage +5 V is 5 V and the second logic operation voltage +0 V is a ground voltage +0 V is described, but the first logic operation voltage +5 V may be higher than or lower than 5 V and the second logic operation voltage +0 V may be higher than or lower than 0 V. Furthermore, each of the first logic input voltage INPUT1 and the second logic input voltage INPUT2 may have the level of the first logic operation voltage +5 V or the level of the second logic operation voltage +0 V.

An operation of setting the states of the first memory cell MC1 and the second memory cell MC2 in order to operate the semiconductor device constructed as above according to an embodiment of the present disclosure as the OR operation logic circuit is described as follows.

The first memory cell MC1 may be written to the set state SET. For example, the first write voltage Write(+) may be supplied from the first voltage supply circuit 10 to the first bit line BL1. The second write voltage Write(-) may be supplied from the third voltage supply circuit 30 to the word line WL0. The first memory cell MC1 that is connected between the first bit line BL and the word line WL0 may be turned on by a difference between the levels of the first write voltage Write(+) and the second write voltage Write(-), and thus may be written to the set state SET.

The second memory cell MC2 may be written to the set state SET. For example, the first write voltage Write(+) may be supplied from the second voltage supply circuit 20 to the second bit line BL2. The second write voltage Write(-) may be supplied from the third voltage supply circuit 30 to the word line WL0. The second memory cell MC2 that is connected between the second bit line BL2 and the word line WL0 may be turned on by a difference between the levels of the first write voltage Write(+) and the second write voltage Write(-), and thus may be written to the set state SET.

The first memory cell MC1 and the second memory cell MC2 may be separately written to the set state SET, and may be substantially simultaneously written to the set state SET. Specifically, each of the first and second memory cells MC1 and MC2 may be written to the set state SET by causing a current to flow from a corresponding one of the first bit line BL1 and the second bit line BL2 to the word line WL0.

After the first memory cell MC1 and the second memory cell MC2 have been written to the set state SET, an OR operation may be performed by using the first memory cell MC1 and the second memory cell MC2 that are in the set state SET.

As illustrated in FIG. 7, a case in which the first memory cell MC1 and the second memory cell MC2 are in the set state SET may be illustrated in the form of an equivalent circuit as in FIG. 8.

An operation of the OR operation is described as follows with reference to FIGS. 7 and 8.

The third voltage supply circuit 30 may supply the second logic operation voltage +0 V to the word line WL0, and may electrically connect the operation output terminal Output to the word line WL0. At this time, the voltage level of each of the word line WL0 and the operation output terminal Output may be the level of the second logic operation voltage +0 V.

The first voltage supply circuit 10 may supply the first logic input voltage INPUT1 to the first bit line BL1.

The second voltage supply circuit 20 may supply the second logic input voltage INPUT2 to the second bit line BL2.

Accordingly, the first logic input voltage INPUT1 that is supplied from the first bit line BL1 and the second logic operation voltage +0 V that is supplied from and the word line WL0 may be supplied to both ends (or terminals) of the first memory cell MC1 in the set state SET. The first memory cell MC1 in the set state SET may be in the state in which a current better flows in a second direction rather than a first direction. In this case, the first direction may be the direction of a current that flows from the word line WL0 to the first bit line BL1 through the first memory cell MC1. Furthermore, the second direction may be the direction of a current that flows from the first bit line BL1 to the word line WL0 through the first memory cell MC1.

For example, the first memory cell MC1 may function as a diode that allows a current to flow in the second direction from the first bit line BL1 to the word line WL0 and substantially block in the first direction from the word line WL0 to the first bit line BL1. As a result, when the voltage level of the first bit line BL1 is higher than the voltage level of the word line WL0, a current may flow in the second direction from the first bit line BL1 to the word line WL0 through the first memory cell MC1.

The second logic input voltage INPUT2 that is supplied from the second bit line BL2 and the second logic operation voltage +0 V that is supplied from the word line WL0 may be supplied to both ends of the second memory cell MC2 in the set state SET. The second memory cell MC2 in the set state SET may be in the state in which a current better flows in a second direction rather than a first direction. In this case, the first direction may be the direction of a current that flows from the word line WL0 to the second bit line BL2 through the second memory cell MC2. Furthermore, the second direction may be the direction of a current that flows from the second bit line BL2 to the word line WL0 through the second memory cell MC2.

For example, the second memory cell MC2 may function as a diode that allows a current to flow in the second direction from the second bit line BL2 to the word line WL0 and substantially block in the first direction from the word line WL0 to the second bit line BL2. As a result, when the voltage level of the second bit line BL2 is higher than the voltage level of the word line WL0, a current may flow in the second direction from the second bit line BL2 to the word line WL0 through the second memory cell MC2.

Accordingly, when the level of one of the first logic input voltage INPUT1 and the second logic input voltage INPUT2 is higher than the level of the second logic operation voltage +0 V, a current may flow into a word line through a memory cell that is supplied with a logic input voltage having a higher level than the second logic operation voltage +0 V. For example, when the level of the first logic input voltage INPUT1, among the first logic input voltage INPUT1 and the second logic input voltage INPUT2, is higher than the level of the second logic operation voltage +0 V, a current may flow from the first bit line BL1 to the word line WL0 through the first memory cell MC1. At this time, the voltage level of the operation output terminal Output having the level of the second logic operation voltage +0 V may rise due to the current that flows into the word line WL0 through the first memory cell MC1. Furthermore, when the level of the second logic input voltage INPUT2, among the first logic input voltage INPUT1 and the second logic input voltage INPUT2, is higher than the level of the second logic operation voltage +0 V, a current may flow from the second bit line BL2 to the word line WL0 through the second memory cell MC2. At this time, the voltage level of the operation output terminal Output having the level of the second logic operation voltage +0 V may rise due to the current that flows into the word line WL0 through the second memory cell MC2. In other words, when one or both of the first logic input voltage INPUT1 and the second logic input voltage INPUT2 have a level higher than the level of the second logic operation voltage +0 V, current(s) flowing through one or both of the first and second memory cells MC1 and MC2 into the resistive element R may increase a voltage level of the operation output terminal Output.

When both the first logic input voltage INPUT1 and the second logic input voltage INPUT2 have the level of the second logic operation voltage +0 V, a current that flows into the word line WL0 through the first memory cell MC1 and the second memory cell MC2 might not be generated. Accordingly, the voltage level of the operation output terminal Output having the level of the second logic operation voltage +0 V may be substantially maintained.

In some embodiments, the level of the first logic input voltage INPUT1 is a high level when the first logic input voltage INPUT1 has substantially the same level as the first logic operation voltage +5 V, and the level of the first logic input voltage INPUT1 is a low level when the first logic input voltage INPUT1 has a lower level than the first logic operation voltage +5 V. Furthermore, in such embodiments, the level of the second logic input voltage INPUT2 is a high level when the second logic input voltage INPUT2 has substantially the same level as the first logic operation voltage +5 V, and the level of the second logic input voltage INPUT2 is a low level when the second logic input voltage INPUT2 has a lower level than the first logic operation voltage +5 V. Furthermore, in these embodiments, the voltage level of the operation output terminal Output is a high level when the voltage level of the operation output terminal Output is substantially the same level as the first logic operation voltage +5 V. In these embodiments, the voltage level of the operation output terminal Output is a low level when the voltage level of the operation output terminal Output is lower than the level of the first logic operation voltage +5 V.

As a result, when the level of any one of the first logic input voltage INPUT1 and the second logic input voltage INPUT2 is a high level, the voltage level of the operation output terminal Output may be changed into a high level. Furthermore, when both the levels of the first logic input voltage INPUT1 and the second logic input voltage INPUT2 are a low level, the voltage level of the operation output terminal Output may maintain a low level. Such a change in the voltage level of the operation output terminal Output for the levels of the first logic input voltage INPUT1 and the second logic input voltage INPUT2 may correspond to the results of an operation of an OR gate.

In other words, the semiconductor device according to the embodiment of FIGS. 7 and 8 may perform an OR operation on the first logic input voltage INPUT1 and the second logic input voltage INPUT2 and output a voltage level of the word line WL0 at the operation output terminal Output as a result of the OR operation. Accordingly, the semiconductor device according to an embodiment of the present disclosure can operate as the OR operation logic circuit.

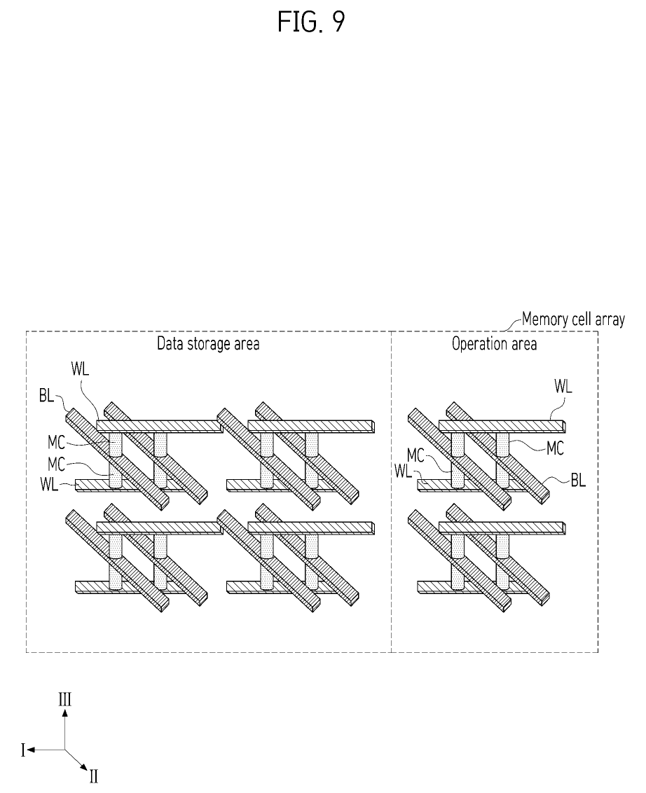

FIG. 9 is a diagram for describing a memory cell array according to an embodiment of the present disclosure.

The semiconductor device according to an embodiment of the present disclosure may write a plurality of memory cells to a specific state (e.g., a set state) and then use the written memory cells in an AND operation and an OR operation. For example, referring to FIGS. 5 and 6, the semiconductor device according to an embodiment of the present disclosure may write the two memory cells to the reset state and then use the two memory cells in the reset state in the AND operation. Furthermore, referring to FIGS. 7 and 8, the semiconductor device according to an embodiment of the present disclosure may write the two memory cells to the set state and then use the two memory cells in the set state in the OR operation.

The memory cells that are used in the AND operation and the OR operation may be manufactured identically with memory cells that store data, and may be components that constitute a memory cell array.

Accordingly, referring to FIG. 9, the semiconductor device according to an embodiment of the present disclosure may include a memory cell array.

The memory cell array may include a plurality of memory cells MC that is connected between a plurality of bit lines BL and a plurality of word lines WL. In this case, each of the plurality of memory cells MC may be disposed at each location at which each of the plurality of bit lines BL and each of the plurality of word lines WL intersect.

Some of the plurality of memory cells MC included in the memory cell array may be used to store data, and the remainder of the plurality of memory cells MC may be used for a logic operation.

The memory cell array may include a data storage area and an operation area. The data storage area may include memory cells that are used to store data. The operation area may include memory cells that are used in a logic operation.

Accordingly, the semiconductor device including the memory cell array according to an embodiment of the present disclosure can perform an operation function in addition to a data storage function. Memory cells in the operation area of the memory cell array may be written to perform various logic operations, thereby ensuring flexibility in design of a semiconductor device including the memory cell array according to an embodiment of the present disclosure. In addition, a semiconductor device according to an embodiment of the present disclosure may omit logic components (e.g., logic transistors) that are separately formed from a memory cell array in a conventional semiconductor device, thereby facilitating implementation of a relatively large number of logical components to improve computation performance.

Although some embodiments of the present disclosure have been described above with reference to the accompanying drawings, various embodiments of the present disclosure are not limited to the above-described embodiments. A person having ordinary knowledge in the art to which the present disclosure pertains may substitute, modify, and change the embodiments in various ways based on the teachings of the present disclosure, and such substitutions, modifications, and changes may belong to various embodiments of the present disclosure.

What is claimed is:

1. A semiconductor device comprising:
a first memory cell that is connected between a first bit line and a word line;
a second memory cell that is connected between a second bit line and the word line;
a first voltage supply circuit configured to supply a first logic input voltage to the first memory cell;
a second voltage supply circuit configured to supply a second logic input voltage to the second memory cell; and
a third voltage supply circuit configured to supply one of a first logic operation voltage and a second logic operation voltage to the word line,
wherein each of the first memory cell and the second memory cell is a component of the device that performs a specific logic operation.

2. The semiconductor device of claim 1, wherein the first memory cell is in a state identical with that of the second memory cell.

3. The semiconductor device of claim 2, wherein the logic operation is an AND operation, and each of the first memory cell and the second memory cell is in a first state, each of the first and second memory cells having been written to the first state by causing a current to flow from the word line to a corresponding one of the first bit line and the second bit line.

4. The semiconductor device of claim 3, wherein the third voltage supply circuit is configured to supply the first logic operation voltage to the word line through a resistance element, the first logic operation voltage having a level higher than the second logic operation voltage.

5. The semiconductor device of claim 4, wherein the device is configured to perform the AND operation on the first logic input voltage and the second logic input voltage and output a voltage level of the word line as a result of the AND operation.

6. The semiconductor device of claim 2, wherein, the logic operation is an OR operation, each of the first memory cell and the second memory cell is in a second state, each of the first and second memory cells having been written to the second state by causing a current to flow from a corresponding one of the first bit line and the second bit line to the word line.

7. The semiconductor device of claim 6, wherein the third voltage supply circuit is configured to supply the second logic operation voltage to the word line through a resistance element, the second logic operation voltage having a level lower than the first logic operation voltage.

8. The semiconductor device of claim 7, wherein the device is configured to perform the OR operation on the first logic input voltage and the second logic input voltage and output a voltage level of the word line as a result of the OR operation.

9. The semiconductor device of claim 2, wherein the first voltage supply circuit and the second voltage supply circuit are configured to supply a second write voltage to the first bit line and the second bit line, respectively, and the third voltage supply circuit is configured to provide a first write voltage to the word line, the first write voltage having a level higher than the second write voltage, to write the first memory cell and the second memory cell to a reset state.

10. The semiconductor device of claim 2, wherein the first voltage supply circuit and the second voltage supply circuit are configured to supply a first write voltage to the first bit line and the second bit line, respectively, and the third voltage supply circuit is configured to supply a second write voltage to the word line, the second write voltage having a level lower than the first write voltage, to write the first memory cell and the second memory cell to a set state.

11. An operating method of a semiconductor device, comprising:
writing a first memory cell that is connected between a first bit line and a word line to a specific state;
writing a second memory cell that is connected between a second bit line and the word line to the specific state;
supplying a first logic input voltage to the first bit line;
supplying a second logic input voltage to the second bit line; and
supplying one of a first logic operation voltage and a second logic operation voltage to the word line depending on a type of logic operation performed by the device including the first memory cell and the second memory cell.

12. The operating method of claim 11, wherein, the logic operation is an AND operation, the first memory cell is written by causing a current to flow from the word line to the first bit line, and the second memory cell is written by causing a current to flow from the word line to the second bit line.

13. The operating method of claim 12, wherein the first logic operation voltage is supplied to the word line through a resistance element.

14. The operating method of claim 12, further comprising checking a voltage level of the word line as a result of the AND operation.

15. The operating method of claim 11, wherein, the logic operation is an OR operation, the first memory cell is written by causing a current to flow from the first bit line to the word line, and the second memory cell is written by causing a current to flow from the second bit line to the word line.

16. The operating method of claim 15, wherein the second logic operation voltage is supplied to the word line through a resistance element.

17. The operating method of claim 15, further comprising checking a voltage level of the word line as a result of the OR operation.

18. A memory device comprising:
a first memory cell that is connected between a first bit line and a word line and configured to function as a first two-terminal component;
a second memory cell that is connected between a second bit line and the word line and configured to function as a second two-terminal component;
a first voltage supply circuit configured to supply a first logic input voltage to the first bit line;
a second voltage supply circuit configured to supply a second logic input voltage to the second bit line; and
a third voltage supply circuit configured to supply one of a first logic operation voltage and a second logic operation voltage to the word line, the first logic operation voltage having a level higher than the second logic operation voltage,
wherein the device performs a specific logic operation on the first logic input voltage and the second logic input voltage and outputs a voltage level of the word line as a result of the logic operation.

19. The memory device of claim 18, wherein the logic operation is an AND operation, and each of the first and second two-terminal components is a diode that allows a current to flow in a first direction from the word line to a corresponding one of the first and second bit lines and block in a second direction from the corresponding one of the first and second bit lines to the word line.

20. The memory device of claim 18, wherein the logic operation is an OR operation, and each of the first and second two-terminal components is a diode that allows a current to flow in a second direction from a corresponding one of the first and second bit lines to the word line and block in a first direction from the word line to the corresponding one of the first and second bit lines.
